(19) United States
(12) Patent Application Publication
(10) Pub. No.: US 2025/0390192 A1
(43) Pub. Date: Dec. 25, 2025

(54) TOUCH SENSING UNIT, DISPLAY DEVICE AND VEHICLE

(71) Applicant: SAMSUNG DISPLAY CO., LTD., Yongin-si (KR)

(72) Inventors: Hyeon Do PARK, Yongin-si (KR); Young Gu KANG, Yongin-si (KR); Min Ji KIM, Yongin-si (KR); Soo Young PARK, Yongin-si (KR); Hyun Sung PARK, Yongin-si (KR); Yu Jin CHOI, Yongin-si (KR)

(21) Appl. No.: 19/027,283

(22) Filed: Jan. 17, 2025

(30) Foreign Application Priority Data
Jun. 24, 2024 (KR) 10-2024-0082089

(51) Int. Cl. G06F 3/044; G06F 3/041; H10K 59/40

(52) U.S. Cl. CPC G06F 3/0446; G06F 3/0412; G06F 3/04164; H10K 59/40

(57) ABSTRACT

A touch sensing unit includes: a substrate; a plurality of first touch electrodes disposed in a touch sensor area of the substrate; a plurality of touch island electrodes disposed between neighboring first touch electrodes; a plurality of connection electrodes connecting the neighboring first touch electrodes to the plurality of touch island electrodes; a plurality of second touch electrodes connected to each other in a connection area that is defined by the neighboring first touch electrodes, the plurality of touch island electrodes and the plurality of connection electrodes, wherein plurality of second touch electrodes are disposed in a touch sensor area of the substrate; and an electrostatic induction electrode connected to the first touch electrode and overlapping the second touch electrode, wherein at least a part of the electrostatic induction electrode overlaps the second touch electrode in the connection area.

### CROSS-REFERENCE TO RELATED APPLICATION

This application claims priority under 35 U.S.C. § 119 to Korean Patent Application No. 10-2024-0082089 filed on Jun. 24, 2024 in the Korean Intellectual Property Office, the disclosure of which is incorporated by reference herein in its entirety.

### TECHNICAL FIELD

The present invention relates to a touch sensing unit, a display device and a vehicle.

### DISCUSSION OF THE RELATED ART

An electronic device such as a smart phone, a tablet PC, a digital camera, a laptop computer, a navigation system and a television (TV), which provides an image to a user, includes a display device for displaying an image. Generally, the display device includes a display panel, which is for generating and displaying an image, and various input devices.

Recently, a touch sensing unit which recognizes a touch input has been widely applied as an input device of a display device mainly in, for example, a smartphone or tablet PC. The touch sensing unit determines whether a user inputs a touch, and calculates a corresponding position as touch input coordinates.

### SUMMARY

According to an embodiment, a touch sensing unit includes: a substrate; a plurality of first touch electrodes disposed in a touch sensor area of the substrate; a plurality of touch island electrodes disposed between neighboring first touch electrodes; a plurality of connection electrodes connecting the neighboring first touch electrodes to the plurality of touch island electrodes; a plurality of second touch electrodes connected to each other in a connection area that is defined by the neighboring first touch electrodes, the plurality of touch island electrodes and the plurality of connection electrodes, wherein plurality of second touch electrodes are disposed in a touch sensor area of the substrate; and an electrostatic induction electrode connected to the first touch electrode and overlapping the second touch electrode, wherein at least a part of the electrostatic induction electrode overlaps the second touch electrode in the connection area.

In an embodiment, a first end of the electrostatic induction electrode is connected to the first touch electrode through a contact hole that penetrates an insulating film, and a second end of the electrostatic induction electrode overlaps the second touch electrode with the insulating film interposed therebetween.

In an embodiment, an extension portion of each of neighboring second touch electrodes of the plurality of second touch electrodes is disposed in the connection area.

In an embodiment, at least a part of the electrostatic induction electrode overlaps the extension portion of a second touch electrode of the neighboring second touch electrodes in the connection area.

In an embodiment, the electrostatic induction electrode is of a plurality of electrostatic induction electrodes, and at least a part of each of the plurality of electrostatic induction electrodes overlaps the second touch electrode in the connection area.

In an embodiment, a number of the plurality of electrostatic induction electrodes and a number of the plurality of connection electrodes are different from each other.

In an embodiment, a length of the electrostatic induction electrode is about 50 □m.

In an embodiment, a width of at least one of the plurality of connection electrodes is about 6.7 μm.

In an embodiment, a width of at least one of the plurality of connection electrodes is about 6.7 μm, and a length of the electrostatic induction electrode is about 50 μm.

According to an embodiment, a display device includes: a display panel; and a touch sensing unit disposed on the display panel, wherein the touch sensing unit includes: a substrate; a plurality of first touch electrodes disposed in a touch sensor area of the substrate; a plurality of touch island electrodes disposed between neighboring first touch electrodes; a plurality of connection electrodes connecting the neighboring first touch electrodes to the plurality of touch island electrodes; a plurality of second touch electrodes connected to each other in a connection area that is defined by the neighboring first touch electrodes, the plurality of touch island electrodes and the plurality of connection electrodes, wherein the plurality of second touch electrodes are disposed in a touch sensor area of the substrate; and an electrostatic induction electrode overlapping the first touch electrode and the second touch electrode, wherein at least a part of the electrostatic induction electrode overlaps the second touch electrode in the connection area.

In an embodiment, a first end of the electrostatic induction electrode is connected to the first touch electrode through a contact hole penetrating an insulating film, and a second end of the electrostatic induction electrode overlaps the second touch electrode with the insulating film interposed therebetween.

In an embodiment, an extension portion of each of neighboring second touch electrodes of the plurality of second touch electrodes is disposed in the connection area.

In an embodiment, at least a part of the electrostatic induction electrode overlaps the extension portion of a second touch electrode of the neighboring second touch electrodes in the connection area.

In an embodiment, the electrostatic induction electrode is of a plurality of electrostatic induction electrode, and at least a part of each of the plurality of electrostatic induction electrodes overlaps the second touch electrode in the connection area.

In an embodiment, a number of the plurality of electrostatic induction electrodes and a number of the plurality of connection electrodes are different from each other.

In an embodiment, a width of at least one of the plurality of connection electrodes is about 6.7 μm, and a length of the electrostatic induction electrode is about 50 μm.

According to an embodiment, a vehicle includes: a body; an interior space defined by the body; and a display device disposed in the interior space, wherein the display device includes: a substrate; a plurality of first touch electrodes disposed in a touch sensor area of the substrate; a plurality of touch island electrodes disposed between neighboring first touch electrodes; a plurality of connection electrodes connecting the neighboring first touch electrodes to the plurality of touch island electrodes; a plurality of second touch electrodes connected to each other in a connection area that is defined by the neighboring first touch electrodes, the plurality of touch island electrodes and the plurality of connection electrodes, wherein the plurality of second touch electrodes are disposed in a touch sensor area of the substrate; and an electrostatic induction electrode connected to the first touch electrode and overlapping the second touch electrode, wherein at least a part of the electrostatic induction electrode overlaps the second touch electrode in the connection area.

In an embodiment, a first end of the electrostatic induction electrode is connected to the first touch electrode through a contact hole penetrating an insulating film, and a second end of the electrostatic induction electrode overlaps the second touch electrode with the insulating film interposed therebetween.

In an embodiment, an extension portion of each of neighboring second touch electrodes of the plurality of second touch electrodes is disposed in the connection area.

In an embodiment, at least a part of the electrostatic induction electrode overlaps the extension portion of a second touch electrode of the neighboring second touch electrodes in the connection area.

According to an embodiment, an electronic device includes: a display device; and a power supply configured to provide power to the display device, wherein the display device includes: a display panel; and a touch sensing unit disposed on the display panel, wherein the touch sensing unit includes: a substrate; a plurality of first touch electrodes disposed in a touch sensor area of the substrate; a plurality of touch island electrodes disposed between neighboring first touch electrodes; a plurality of connection electrodes connecting the neighboring first touch electrodes to the plurality of touch island electrodes; a plurality of second touch electrodes connected to each other in a connection area that is defined by the neighboring first touch electrodes, the plurality of touch island electrodes and the plurality of connection electrodes, wherein the plurality of second touch electrodes are disposed in a touch sensor area of the substrate; and an electrostatic induction electrode connected to the first touch electrode and overlapping the second touch electrode, wherein at least a part of the electrostatic induction electrode overlaps the second touch electrode in the connection area.

In an embodiment, a first end of the electrostatic induction electrode is connected to the first touch electrode through a contact hole that penetrates an insulating film that is disposed on the electrostatic induction electrode, and a second end of the electrostatic induction electrode overlaps the second touch electrode with the insulating film interposed therebetween.

In an embodiment, neighboring second touch electrodes of the plurality of second touch electrodes are connected to each other through an extension portion that is disposed in the connection area.

In an embodiment, at least a portion of the electrostatic induction electrode overlaps the extension portion in the connection area.

In an embodiment, the electrostatic induction electrode does not contact the extension portion.

### BRIEF DESCRIPTION OF THE DRAWINGS

The above and other aspects and features of the present invention will become more apparent by describing in detail exemplary embodiments thereof with reference to the attached drawings, in which:

FIG. 1 is a perspective view illustrating a display device according to an embodiment;

FIG. 2 is a plan view illustrating a display device according to an embodiment;

FIG. 3 is a cross-sectional view illustrating an example taken along line I-I′ of FIG. 2;

FIG. 4 is a plan view showing in detail an example of the display unit of FIG. 3;

FIG. 5 is a plan view showing in detail an example of the touch sensing unit of FIG. 3;

FIG. 6 is an enlarged plan view showing an example of area A of FIG. 5;

FIG. 7 is a cross-sectional view showing an example of line II-II′ of FIG. 6;

FIG. 8 is a cross-sectional view showing an example of line III-III′ of FIG. 6;

FIG. 9 is an enlarged plan view showing an example of area A of FIG. 5;

FIG. 10 is a diagram for explaining effects of the electrostatic induction electrode ESD according to an embodiment;

FIG. 11 is a schematic diagram illustrating a vehicle including the display device according to an embodiment; and

FIG. 12 is a block diagram illustrating an electronic device according to an embodiment.

### DETAILED DESCRIPTION OF THE EMBODIMENTS

Features of the present invention will now be described more fully hereinafter with reference to the accompanying drawings, in which embodiments of the present invention are shown. This invention may, however, be embodied in different forms and should not be construed as limited to the embodiments set forth herein.

It will also be understood that when a layer is referred to as being “on” another layer or substrate, it can be directly on the other layer or substrate, or intervening layers may also be present.

The same reference numbers indicate the same components throughout the specification and drawings, and thus, redundant descriptions may be omitted or briefly discussed. In the attached figures, various thicknesses, lengths, and angles are shown and while the arrangement shown does indeed represent an embodiment of the present disclosure, it is to be understood that modifications of the various thicknesses, lengths, and angles may be possible within the spirit and scope of the present disclosure and the present disclosure is not necessarily limited to the particular thicknesses, lengths, and angles shown.

Although the terms “first”, “second”, etc. may be used herein to describe various elements, these elements, should not be limited by these terms. These terms may be used to distinguish one element from another element. For example, a first element discussed below may be termed a second element without departing from teachings of one or more embodiments. The description of an element as a “first” element might not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

It is to be understood that “about” or “approximately” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” can mean within one or more standard deviations, or within ±30%, 20%, 10% or 5% of the stated value.

Features of various embodiments of the present invention may be combined partially or totally. As will be clearly appreciated by those skilled in the art, technically various interactions and operations are possible. Various embodiments can be practiced individually or in combination.

Hereinafter, exemplary embodiments will be described with reference to the accompanying drawings.

Embodiments of the present invention pertains to a touch sensing unit designed to increase the functionality and reliability of display devices, particularly by mitigating damage from static electricity. The touch sensing unit includes multiple layers of electrodes, including first and second touch electrodes, touch island electrodes, and connection electrodes, arranged on a substrate within a touch sensor area. The touch sensing unit further includes electrostatic induction electrodes that overlap the second touch electrodes in connection areas, providing enhanced static electricity management.

This electrode design enables the touch sensing unit to efficiently channel and dissipate static charges, preventing electrical damage to certain connection electrodes. By overlapping the electrostatic induction electrodes with the second touch electrodes at connection areas, the unit ensures better distribution and absorption of static electricity. This configuration may increase durability and performance of the touch sensing unit under varying environmental conditions.

The invention may be integrated into a display device, which combines the touch sensing unit with a display panel. The device supports interaction through touch input while also serving as a versatile display for vehicles, consumer electronics, and portable devices. The display device with the touch sensing unit may adaptable, supporting flexible and curved substrates, making it suitable for applications like foldable or rollable displays.

Additionally, the touch sensing unit and display device may be incorporated into vehicles, where reliability and user interaction are desirable. By incorporating this technology into automotive displays, the present invention enables interaction within vehicle interiors while reducing the risk of static damage.

The effects of the present invention are not limited to the above-described effects, and other effects which are not described herein may exist in view of the following description.

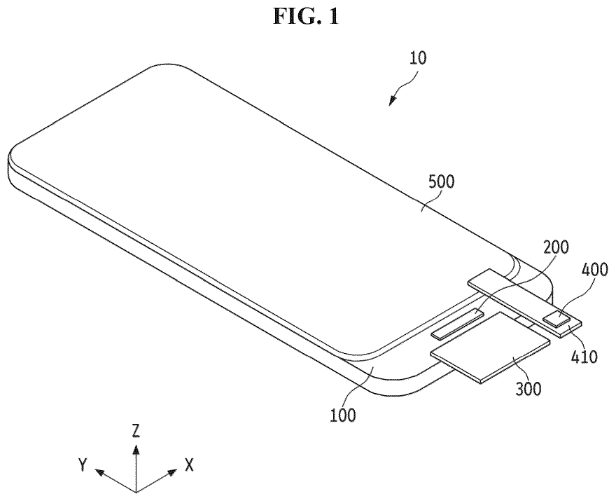

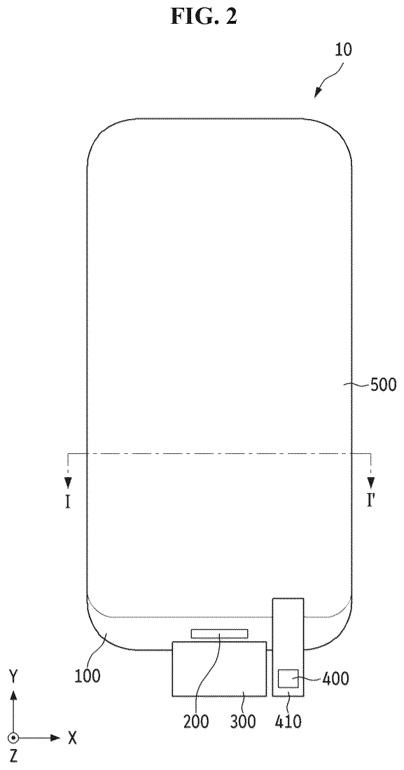

FIG. 1 is a perspective view illustrating a display device according to an embodiment. FIG. 2 is a plan view illustrating a display device according to an embodiment.

In this specification, “upper portion,” “top,” and “top surface” refer to the direction, i.e., a Z-axis direction (e.g., a positive Z-axis direction), in which a touch sensing unit 500 is disposed when viewed with respect to a display panel 100, and “lower portion”, “bottom”, and “bottom surface” refer to the direction, i.e., a direction opposite to the Z-axis direction (e.g., a negative Z-axis direction), in which the display panel 100 is disposed when viewed with respect to the touch sensing unit 500. Further, “left”, “right”, “upper” and “lower” indicate directions when the display panel 100 is viewed from above. For example, the term “left” indicates a direction opposite to an X-axis direction (e.g., a negative X-axis direction), the term “right” indicates the X-axis direction (e.g., a positive X-axis direction), the term “upper” indicates a Y-axis direction (e.g., a positive Y-axis direction), and the term “lower” indicates a direction opposite to the Y-axis direction (e.g., a negative Y-axis direction).

Referring to FIGS. 1 and 2, a display device 10, which is a device for displaying a moving image or a still image, may be used as a display screen of various devices, such as a vehicle display, a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). The display device 10 may be any one of, for example, an organic light-emitting display device, a liquid crystal display device, a plasma display device, a field emission display device, an electrophoretic display device, an electrowetting display device, a quantum dot light-emitting display device, a micro LED display device, and the like. The following description is directed to the case where the display device 10 is an organic light-emitting display device, but the present invention is not limited thereto.

The display device 10 according to an embodiment includes the display panel 100, a display driving circuit 200, a display circuit board 300, a touch driving circuit 400, a touch circuit board 410, and the touch sensing unit 500.

The display panel 100 may be formed in a rectangular shape, in plan view, having short sides in a first direction (X-axis direction) and long sides in a second direction (Y-axis direction) crossing the first direction (X-axis direction). The corner where the short side in the first direction (X-axis direction) and the long side in the second direction (Y-axis direction) meet may be rounded to have a predetermined curvature or may be right-angled. The planar shape of the display panel 100 is not limited to the rectangular shape, and may be formed in, for example, another polygonal shape, a circular shape or an elliptical shape.

The display panel 100 may be formed flat, but the present invention is not limited thereto, and may include curved portions formed at left and right ends. In this case, the curved portions may have a constant curvature or a changing curvature. In addition, the display panel 100 may be formed flexibly so that it can be curved, bent, folded, or rolled.

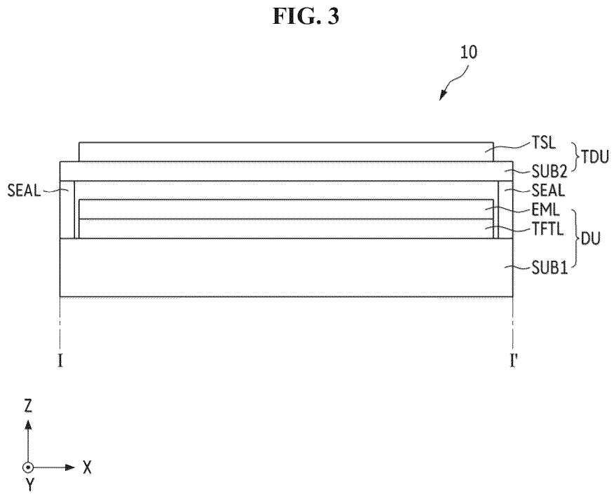

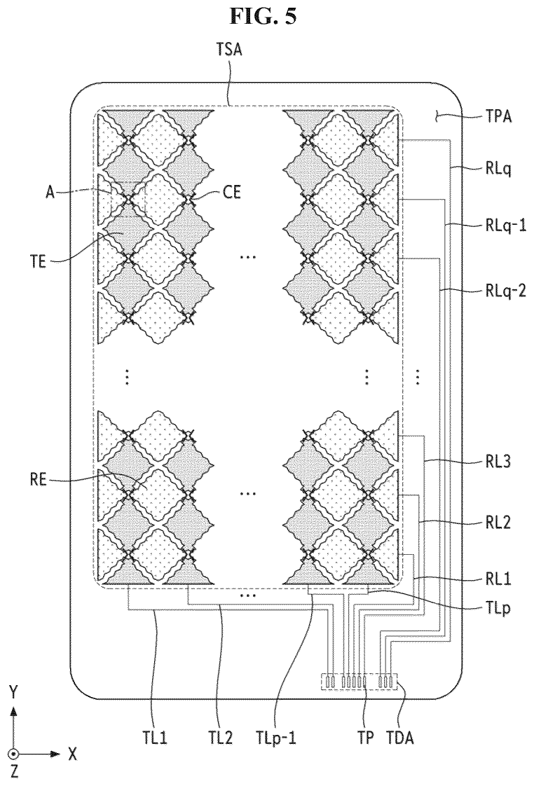

The display panel 100 may include pixels and display electrode pads. The pixels may be disposed in a display area to display an image, and the display electrode pads may be disposed in a non-display area that is located around the display area. The display electrode pads may be disposed on the display panel 100 at one edge of the display panel 100 and electrically connected to the display circuit board 300. The display panel 100 will be described in detail later with reference to FIGS. 3 and 5.

The display driving circuit 200 outputs signals and voltages for driving the display panel 100. For example, the display driving circuit 200 may supply data voltages to data lines. Further, the display driving circuit 200 may supply a power voltage to the power line, and may supply scan control signals to the scan driver. The display driving circuit 200 may be formed as an integrated circuit (IC) and bonded to the display panel 100 by a chip on glass (COG) method, a chip on plastic (COP) method, or an ultrasonic bonding method. The display driving circuit 200 may be bonded on the display panel 100 that is exposed without being covered by the touch sensing unit 500. In addition, the display driving circuit 200 may be mounted on the circuit board 300.

The display circuit board 300 may be attached onto display electrode pads of the display panel 100 by using an anisotropic conductive film. Accordingly, lead lines of the display circuit board 300 may be electrically connected to the display electrode pads of the display panel 100. For example, the display circuit board 300 may be a flexible printed circuit board, a printed circuit board, or a flexible film such as a chip on film.

The touch sensing unit 500 may be disposed on the display panel 100. The touch sensing unit 500 may be formed in a rectangular shape, in plan view, having short sides in the first direction (X-axis direction) and long sides in the second direction (Y-axis direction). The corner where the short side in the first direction (X-axis direction) and the long side in the second direction (Y-axis direction) meet may be rounded to have a predetermined curvature or may be right-angled. The planar shape of the touch sensing unit 500 is not limited to the rectangular shape, and may be formed in, for example, another polygonal shape, a circular shape or an elliptical shape. The planar shape of the touch sensing unit 500 may be similar to that of the display panel 100.

The touch sensing unit 500 may be formed flat, but the present invention is not limited thereto, and may include curved portions formed at left and right ends. In this case, the curved portions may have a constant curvature or a changing curvature. In addition, similarly to the display panel 100, the touch sensing unit 500 may be formed flexibly so that it can be curved, bent, folded, or rolled.

The touch sensing unit 500 may include touch electrodes and touch electrode pads TP. The touch electrodes may be disposed in a touch sensor area and may detect a user's touch, and the touch electrode pads TP may be disposed in a touch peripheral area that is around or adjacent to the touch sensor area. The touch electrode pads TP may be disposed on the touch sensing unit 500 at one edge of the touch sensing unit 500 and electrically connected to the touch circuit board 410.

The touch sensing unit 500 will be described in detail later with reference to FIGS. 3 and 5. FIGS. 1 and 2 illustrate that the touch sensing unit 500 is a touch panel that is separate from the display panel 100, but the present invention is not limited thereto. That is, as shown in FIGS. 1 and 2, the touch sensing unit 500 may be disposed directly on a thin film encapsulation layer of the display panel 100.

The touch circuit board 410 may be attached on the touch electrode pads of the touch sensing unit 500 by using an anisotropic conductive film. Accordingly, lead lines of the touch circuit board 410 may be electrically connected to the touch electrode pads of the touch sensing unit 500. The touch circuit board 410 may be, for example, a flexible printed circuit board, a printed circuit board, or a flexible film such as a chip-on film.

The touch driving circuit 400 may be connected to the touch electrodes of the touch sensing unit 500. The touch driving circuit 400 applies touch driving signals to the touch electrodes of the touch sensing unit 500 and measures the capacitance values of the touch electrodes. The touch driving signal may be a signal having a plurality of driving pulses. The touch driving circuit 400 may determine whether or not touch is inputted based on the capacitance values, and may calculate touch coordinates at which touch is inputted. The touch driving circuit 400 may be formed as an integrated circuit (IC) and disposed on the touch circuit board 300.

FIG. 3 is a cross-sectional view illustrating an example taken along line I-I′ of FIG. 2.

Referring to FIG. 3, the display device 10 may include a display unit DU, a touch sensing unit TDU, and a bonding member SEAL that bonds the display unit DU to the touch sensing unit TDU.

The display unit DU may include a first substrate SUB1, a thin film transistor layer TFTL, and a light-emitting element layer EML.

The first substrate SUB I may be a rigid substrate or a flexible substrate which can be bent, folded or rolled. The first substrate SUB1 may be made of an insulating material such as glass, quartz, or polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. In addition, the first substrate SUB1 may include a metal material.

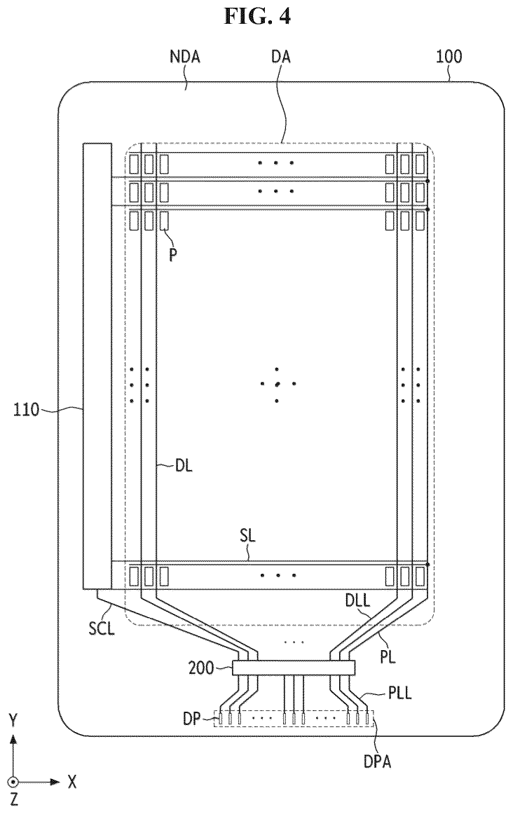

The thin film transistor layer TFTL may be disposed on the first substrate SUB1. In the thin film transistor layer TFTL, thin film transistors of the respective pixels, scan lines, data lines, power lines, scan control lines, data connection lines, which connect the display driving circuit 200 to the data lines, pad connection lines, which connect the display driving circuit 200 to the display electrode pads, and so forth may be disposed. Each of the thin film transistors may include a gate electrode, a semiconductor layer, a source electrode, and a drain electrode. When a scan driver 110 is disposed in a non-display area NDA of the display panel 100 as shown in FIG. 4, the scan driver 110 may include thin film transistors.

The thin film transistor layer TFTL may be disposed in the display area DA and the non-display area NDA. For example, thin film transistors, scan lines, data lines, and power lines of each of the pixels of the thin film transistor layer TFTL may be disposed in the display area DA. The scan control lines, the data connection lines, and the pad connection lines of the thin film transistor layer TFTL may be disposed in the non-display area NDA.

A light-emitting element layer EML may be disposed on the thin film transistor layer TFTL. The light-emitting element layer EML may include pixels in which a first electrode, a light-emitting layer, and a second electrode are sequentially stacked on the thin film transistor layer TFTL to emit light, and a pixel defining film defining the pixels. For example, the pixel defining film may define the light emission areas of the pixels. The pixels of the light-emitting element layer EML may be disposed in the display area DA.

The light-emitting layer may be an organic light-emitting layer including an organic material. In this case, the light-emitting layer may include a hole transporting layer, an organic light-emitting layer, and an electron transporting layer. When the first electrode is applied with a predetermined voltage through the thin film transistor of the thin film transistor layer TFTL and the second electrode is applied with a cathode voltage, holes and electrons are transferred to the organic light-emitting layer through a hole transporting layer and an electron transporting layer, respectively and are combined with each other to emit light in the organic light-emitting layer. In this case, the first electrode may be an anode electrode and the second electrode may be a cathode electrode.

The touch sensing unit TDU may include a second substrate SUB2 and a touch sensor layer TSL.

The second substrate SUB2 may be a rigid substrate or a flexible substrate which can be bent, folded or rolled. For example, the second substrate SUB2 may be made of an insulating material such as glass, quartz, or polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. In addition, the second substrate SUB2 may include a metal material. Additionally, the second substrate SUB2 may serve as an encapsulation substrate that encapsulates the light-emitting element layer EML.

The touch sensor layer TSL may be disposed on the second substrate SUB2. The touch sensor layer TSL may include touch electrodes for detecting a user's touch in a capacitive manner, touch electrode pads, and touch signal lines connecting the touch electrode pads to the touch electrodes. For example, the touch sensor layer TSL may sense a user's touch using a self-capacitance method or a mutual capacitance method.

As shown in FIG. 5, the touch electrodes of the touch sensor layer TSL may be disposed in a touch sensor area TSA that overlaps the display area DA. The touch signal lines and the touch electrode pads TP of the touch sensor layer TSL may be disposed in a touch peripheral area TPA that overlaps the non-display area NDA. The touch peripheral area TPA may be disposed around or adjacent to the touch sensor area TSA.

A polarizing film and a cover window may be disposed on the touch sensor layer TSL. In this case, the polarizing film may be disposed on the touch sensor layer TSL, and the cover window may be attached to the polarizing film by a transparent bonding member.

The bonding member SEAL may bond the first substrate SUB1 of the display unit DU and the second substrate SUB2 of the touch sensing unit TDU to each other. The bonding member SEAL may be, for example, a frit bonding layer, an ultraviolet curable resin, or a heat curable resin, but the present invention is not limited thereto.

Although FIG. 3 illustrates that an empty space exists between the light-emitting element layer EML and the second substrate SUB2, the embodiment of the present invention is not limited thereto. For example, a filling film, an encapsulation layer, or the like may be disposed between the light-emitting element layer EML and the second substrate SUB2. The filling film may be an epoxy filling film or a silicon filling film.

FIG. 4 is a plan view showing in detail an example of the display unit of FIG. 3. For simplicity of description, FIG. 4 only illustrates pixels P, scan lines SL, data lines DL, a power line PL, scan control lines SCL, the scan driver 110, the display driving circuit 200, display electrode pads DP, data connection lines DLL, and pad connection lines PLL of the display unit DU.

Referring to FIG. 4, the display panel 100 may include a display area DA where pixels are disposed to display an image, and a non-display area NDA that is a peripheral area around the display area DA. The non-display area NDA may be defined as an area from the boundary of the display area DA to the edge of the display panel 100.

The scan lines SL, the data lines DL, the power line PL, and the pixels P may be arranged in the display area DA. The scan lines SL may be disposed side by side in the second direction (Y-axis direction), and the data lines DL may be disposed side by side in the first direction (X-axis direction) intersecting the second direction (Y-axis direction). The power line PL may include at least one line, which is formed in parallel with the data lines DL in the second direction (Y-axis direction), and a plurality of lines, which are branched from the at least one line in the first direction (X-axis direction).

Each of the pixels P may be connected to at least one of the scan lines SL, one of the data lines DL, and the power line PL. Each of the pixels P may include thin film transistors including a driving transistor and at least one switching transistor, an organic light-emitting diode, and a capacitor. When a scan signal is applied from the scan line SL, each of the pixels P may receive the data voltage of the data line DL and supply a driving current to an organic light-emitting diode in response to the data voltage that is applied to the gate electrode to emit light.

The scan driver 110, the display driving circuit 200, the scan control lines SCL, the data connection lines DLL, and the pad connection lines PLL may be disposed in the non-display area NDA.

The scan driver 110 is connected to the display driving circuit 200 through at least one scan control line SCL. Therefore, the scan driver 110 may receive a scan control signal of the display driving circuit 200. The scan driver 110 generates scan signals according to the scan control signal and supplies the scan signals to the scan lines SL.

Although FIG. 4 illustrates that the scan driver 110 is disposed in the non-display area NDA located at one outer side of the display area DA, the present invention is not limited thereto. For example, the scan driver 110 may be disposed in the non-display area NDA that is located at both outer sides (e.g., opposing sides) of the display area DA.

The display driving circuit 200 is connected to the display electrode pads DP of the display pad area DPA through display connection lines PLL, and the display driving circuit 200 receives digital video data and timing signals. The display driving circuit 200 converts the digital video data into analog positive/negative data voltages and supplies them to the data lines DL through the data connection lines DLL. Further, the display driving circuit 200 generates and supplies a scan control signal to the scan driver 110 through the scan control line SCL, for controlling the scan driver 110. The pixels P to which the data voltages are to be supplied may be selected by the scan signals of the scan driver 110, and the data voltages may be supplied to the selected pixels P. The display driving circuit 200 may be formed as an integrated circuit (IC) and disposed on a substrate SUB using a chip on glass (COG) method, a chip on plastic (COP) method, or an ultrasonic bonding method.

FIG. 5 is a plan view showing in detail an example of the touch sensing unit of FIG. 3.

Referring to FIG. 5, the touch sensing unit TDU includes the touch sensor area TSA for sensing user's touch and the touch peripheral area TPA disposed around the touch sensor area TSA. The touch sensor area TSA may overlap the display area DA of the display unit DU, and the touch peripheral area TPA may overlap the non-display area NDA of the display unit DU.

The touch sensor area TSA may have a rectangular shape in plan view; however, the present invention is not limited thereto.

First touch electrodes TE and the second touch electrodes RE may be disposed in the touch sensor area TSA. The first touch electrodes TE and the second touch electrodes RE may be disposed apart from each other. The first touch electrodes TE may be arranged in the second direction (Y-axis direction) in a plurality of columns, and the plurality of columns of the first touch electrodes TE may be arranged in the first direction (X-axis direction). The second touch electrodes RE may be arranged in the first direction (X-axis direction) in a plurality of rows, and the plurality of rows of the second touch electrodes RE may be arranged in the second direction (Y-axis direction). The first touch electrodes TE disposed in the second direction (Y-axis direction) in each of the plurality of columns may be electrically connected to each other. In addition, the second touch electrodes RE disposed in the first direction (X-axis direction) in each of the plurality of rows may be electrically connected to each other.

The first touch electrodes TE and the second touch electrodes RE may be disposed in all of a first touch sensor area, a second touch sensor area, and a third touch sensor area. The first touch electrodes TE and the second touch electrodes RE disposed in the first touch sensor area may be formed in a diamond shape or a triangle shape in plan view. For example, the first touch electrodes TE and the second touch electrodes RE disposed at the edge of the first touch sensor area may be formed in a triangular shape in plan view, and the other first and second touch electrodes TE and RE may be formed in a diamond shape in plan view. In each of the second touch sensor area and the third touch sensor area, at least one first touch electrode TE and at least one second touch electrode RE may have an irregular shape. Further, to prevent a moire phenomenon from occurring due to the first and second touch electrodes TE and RE when watching an image of the display device 10, the first touch electrodes TE and the second touch electrodes RE may have uneven sides in plan view. In addition, the planar shape of the first touch electrodes TE and the second touch electrodes RE disposed in the first touch sensor area is not limited to the shape shown in FIG. 5.

To prevent the first touch electrodes TE and the second touch electrodes RE from being short-circuited in their intersection areas, the first touch electrodes TE, which are adjacent to each other in the second direction (Y-axis direction), may be connected to each other through a connection electrode CE. In this case, the first touch electrodes TE and the second touch electrodes RE may be disposed in one layer, and the connection electrode CE may be disposed in another layer that is different from where the first touch electrodes TE and the second touch electrodes RE are disposed. For example, the first touch electrodes TE may be disposed on the same layer as the second touch electrodes RE. As a result, the first touch electrodes TE, which are electrically connected to each other in the second direction (Y-axis direction), and the second touch electrodes RE, which are electrically connected to each other in the first direction (X-axis direction), may be electrically insulated from each other.

First touch signal lines TL1 to TLp (p is a positive integer equal to or greater than 2), second touch signal lines RL1 to RLq (q is a positive integer equal or greater than 2), and the electrode pads TP may be disposed in the touch peripheral area TPA.

First ends of the first touch signal lines TL1 to TLp may be connected to the first touch electrodes TE disposed on the first side of the touch sensor area TSA. Among the four sides of the touch sensor area TSA, the first side of the touch sensor area TSA may be the side closest to the touch pad area TDA where the touch electrode pads TP are disposed. In addition, the second side of the touch sensor area TSA may be the side opposite to the first side, and the third and fourth sides of the touch sensor area TSA may be the sides disposed between the first side and the second side. At this time, the third side may be, for example, the side where the above-described second touch signal lines RL1 to RLq are disposed, and the fourth side may be the side opposite to the third side. The other ends (e.g., second ends) of the first touch signal lines TL1 to TLp may be connected to some of the touch electrode pads TP in the touch pad area TDA. For example, the first touch signal lines TL1 to TLp serve to connect the first touch electrodes TE disposed on the first side of the touch sensor area TSA and some touch electrode pads TP of the touch pad area TDA to each other.

For example, as shown in FIG. 5, the first-first touch signal line TL1 may be electrically connected to the first touch electrodes TE disposed in the first column of the touch sensor area TSA, and the first-second touch signal line TL2 may be electrically connected to the first touch electrodes TE disposed in the second column of the touch sensor area TSA. In addition, the first-(p−1)^{th} touch signal line TLp−1 may be electrically connected to the first touch electrodes TE disposed in the (p−1)^{th} column of the touch sensor area TSA, and the first-p^{th} touch signal line TLp may be electrically connected to the first touch electrodes TE disposed in the p^{th} column of the touch sensor area TSA. At this time, the first column of the touch sensor area TSA is the column located on the leftmost side of the touch sensor area TSA, and the p^{th} column of the touch sensor area TSA is the column located on the rightmost side of the touch sensor area TSA.

First ends of the second touch signal lines RL1 to RLq may be connected to the second touch electrodes RE that are disposed on the third side of the touch sensor area TSA. The other ends (e.g., second ends) of the second touch signal lines RL1 to RLq may be connected to the remaining touch electrode pads TP in the touch pad area TDA. For example, the second touch signal lines RL1 to RLq serve to connect the second touch electrodes RE disposed on the third side of the touch sensor area TSA to the remaining touch electrode pads TP of the touch pad area TDA.

For example, as shown in FIG. 5, the second-first touch signal line RL1 may be electrically connected to the second touch electrodes RE that are disposed in the first row of the touch sensor area TSA, which is most adjacent to the first side of the touch sensing area when compared to the remaining rows of the second touch electrodes RE. Further, the second-second touch signal lines RL2 may be electrically connected to the second touch electrodes RE that are disposed in the second row of the touch sensor area TSA, and the second-third touch signal line RL3 may be electrically connected to the second touch electrodes RE that are disposed in the third row of the touch sensor area TSA. In addition, the second-(q−2)^{th} touch signal line RLq−2 may be electrically connected to the second touch electrodes RE that are disposed in the (q−2)^{th} row of the touch sensor area TSA. Further, the second-(q−1)^{th} touch signal line RLq−1 may be electrically connected to the second touch electrodes RE that are disposed in the (q−1)^{th} row of the touch sensor area TSA, and the second-q^{th} touch signal line RLq may be electrically connected to the second touch electrodes RE that are disposed in the q^{th} row of the touch sensor area TSA.

The touch electrode pads TP may be disposed on one side of the second substrate SUB2. The touch circuit board 410 may be attached to the touch electrode pads TP by using an anisotropic conductive film. Accordingly, the touch electrode pads TP may be electrically connected to the touch circuit board 410.

The first touch electrodes TE and the second touch electrodes RE may be driven using a mutual capacitance method or a self-capacitance method.

First, when the first touch electrodes TE and the second touch electrodes RE are driven in a mutual capacitance manner, touch driving signals are supplied to the first touch electrodes TE through the first touch signal lines TL1 to TLp to charge mutual capacitances formed in the intersection areas of the first and second touch electrodes TE and RE. Then, the charge change amounts of the mutual capacitances are measured through the second touch electrodes RE, and it is determined whether a touch input occurs according to the charge change amounts of the mutual capacitances. The touch driving signal may be a signal having a plurality of touch driving pulses.

Second, when the first touch electrodes TE and the second touch electrodes RE are driven in the self-capacitance manner, touch driving signals are supplied to all of the first touch electrodes TE and the second touch electrodes RE through the first touch signal lines TL1 to TLp and the second touch signal lines RL1 to RLq to charge self-capacitances of the first touch electrodes TE and the second touch electrodes RE. Then, charge variation amounts in the self-capacitances are measured through the first touch signal lines TL1 to TLp and the second touch signal lines RL1 to RLq, and it is determined whether or not a touch input has been made based on the charge variation amounts in the self-capacitances.

For simplicity of description, the following description will mainly focus on driving in the mutual capacitance method in which a plurality of touch driving pulses are applied to the first touch electrodes TE, and charge variation amounts in the mutual capacitances are measured through the second touch signal lines RL1 to RLq connected to the second touch electrodes RE. In this case, the first touch electrodes TE may function as touch driving electrodes, the second touch electrodes RE may function as touch sensing electrodes, the first touch signal lines TL1 to TLp may function as touch driving lines, and the second touch signal lines RL1 to RLq may function as touch sensing lines.

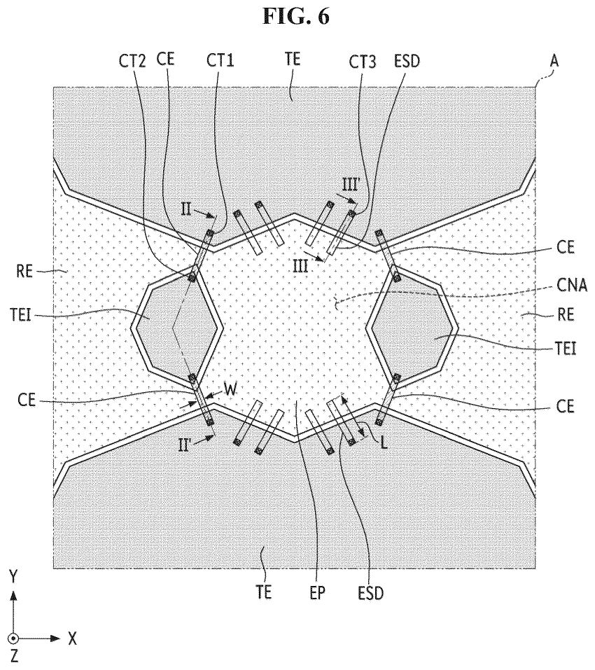

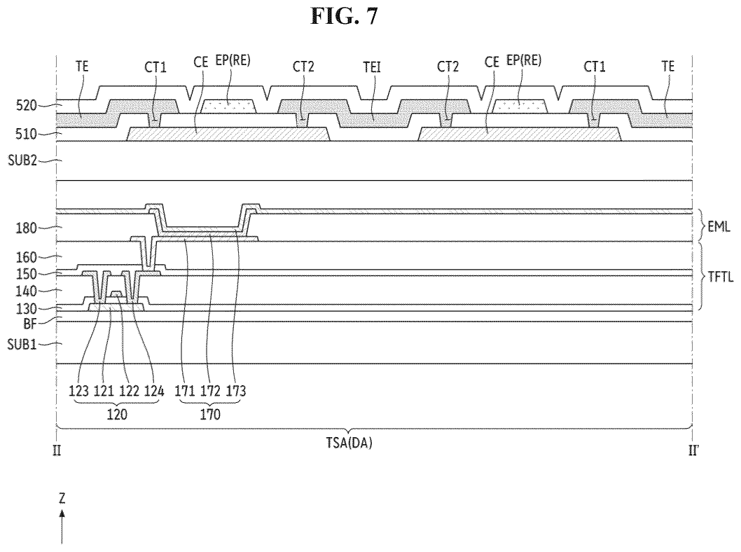

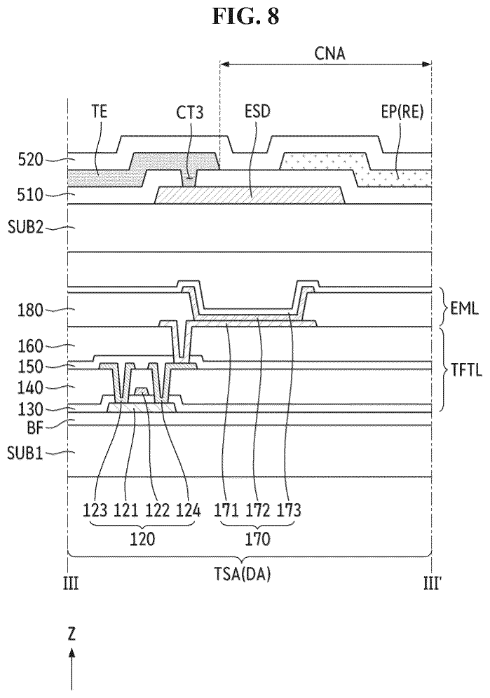

FIG. 6 is an enlarged plan view showing an example of area A of FIG. 5. FIG. 7 is a cross-sectional view showing an example of line II-II′ of FIG. 6, and FIG. 8 is a cross-sectional view showing an example of line III-III′ of FIG. 6.

Referring to FIGS. 6, 7, and 8, the thin film transistor layer TFTL is disposed on the first substrate SUB1. The thin film transistor layer TFTL includes thin film transistors 120, a gate insulating film 130, an interlayer insulating film 140, a passivation film 150, and a planarization film 160.

A buffer film BF may be disposed on one surface of the first substrate SUB1. The buffer film BF may be disposed on the first substrate SUB1 to protect the thin film transistors 120 and an organic light-emitting layer 172 of the light-emitting element layer EML from moisture that may permeate through the substrate SUB that may be susceptible to moisture permeation. The buffer film BF may be formed of a plurality of inorganic films that are alternately stacked on each other. For example, the buffer film BF may be formed of multiple films in which one or more inorganic films of a silicon nitride layer, a silicon oxynitride layer, a silicon oxide layer, a titanium oxide layer and an aluminum oxide layer are alternately stacked. In an embodiment, the buffer film BF may be omitted.

The thin film transistor 120 is disposed on the buffer film BF. The thin film transistor 120 includes an active layer 121, a gate electrode 122, a source electrode 123, and a drain electrode 124. Although the thin film transistor 120 is illustrated in FIG. 7 to be formed as an upper gate (top gate) structure in which the gate electrode 122 is positioned on (e.g. above) the active layer 121, the present invention is not limited thereto. For example, the thin film transistors 120 may be formed as a lower gate (bottom gate) structure in which the gate electrode 122 is positioned below the active layer 121 or a double gate structure in which the gate electrode 122 is positioned both above and below the active layer 121.

The active layer 121 is disposed on the buffer film BF. The active layer 121 may be an organic semiconductor such as polycrystalline silicon, monocrystalline silicon, low-temperature polycrystalline silicon, and amorphous silicon, or an oxide semiconductor. A light blocking layer for blocking external light incident on the active layer 121 may be disposed between the buffer film BF and the active layer 121.

The gate insulating film 130 may be formed on the active layer 121. The gate insulating film 130 may be formed of an inorganic film, for example, a silicon nitride layer, a silicon oxynitride layer, a silicon oxide layer, a titanium oxide layer, or an aluminum oxide layer.

The gate electrode 122 and a gate line may be disposed on the gate insulating film 130. The gate electrode 122 and the gate line may be formed as a single layer or multiple layers made of any one of, for example, molybdenum (Mo), aluminum (Al), chromium (Cr), gold (Au), titanium (Ti), nickel (Ni), neodymium (Nd) and copper (Cu) or an alloy thereof.

The interlayer insulating film 140 may be disposed on the gate electrode 122 and the gate line. The interlayer insulating film 140 may be formed of an inorganic film, for example, a silicon nitride layer, a silicon oxynitride layer, a silicon oxide layer, a titanium oxide layer, or an aluminum oxide layer.

The source electrode 123 and the drain electrode 124 may be disposed on the interlayer insulating film 140. Each of the source electrode 123 and the drain electrode 124 may be connected to the active layer 121 through a contact hole penetrating the gate insulating film 130 and the interlayer insulating film 140. The source electrode 123 and the drain electrode 124 may be formed as a single layer or multiple layers made of any one of, for example, molybdenum (Mo), aluminum (Al), chromium (Cr), gold (Au), titanium (Ti), nickel (Ni), neodymium (Nd) and copper (Cu) or an alloy thereof.

The passivation film 150 for insulating the thin film transistor 120 may be disposed on the source electrode 123 and the drain electrode 124. The passivation film 150 may be formed of an inorganic film, for example, a silicon nitride layer, a silicon oxynitride layer, a silicon oxide layer, a titanium oxide layer, or an aluminum oxide layer.

The planarization film 160 for flattening a stepped portion formed by the thin film transistors 120 may be disposed on the passivation film 150. The planarization film 160 may be formed of an organic film such as acryl resin, epoxy resin, phenolic resin, polyamide resin, polyimide resin and the like.

The light-emitting element layer EML is disposed on the thin film transistor layer TFTL. The light-emitting element layer EML includes light-emitting elements 170 and a pixel defining film 180.

The light-emitting elements 170 and the pixel defining film 180 are disposed on the planarization film 160. Each of the light-emitting elements 170 may include a first electrode 171, the organic light-emitting layer 172, and a second electrode 173.

The first electrode 171 may be disposed on the planarization film 160. The first electrode 171 is connected to the source electrode 123 of the thin film transistor 120 through a contact hole that penetrates the passivation film 150 and the planarization film 160.

In a top emission structure in which light is emitted toward the second electrode 173 when viewed with respect to the organic light-emitting layer 172, the first electrode 171 may be formed of a metal material having high reflectivity such as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO. The APC alloy is an alloy of silver (Ag), palladium (Pd) and copper (Cu).

In a bottom emission structure in which light is emitted toward the first electrode 171 when viewed with respect to the organic light-emitting layer 172, the first electrode 171 may be made of a transparent metal oxide (TCO), such as ITO or IZO, capable of transmitting light, or a semi-transmissive conductive material such as magnesium (Mg), silver (Ag), or an alloy of magnesium (Mg) and silver (Ag). In this case, when the first electrode 171 is formed of a semi-transmissive metal material, the light emission efficiency can be increased due to a micro-cavity effect.

The pixel defining film 180 may be disposed to separate the first electrode 171 from other first electrodes on the planarization film 250 to define a pixel P such that an emission area of the pixel P is defined. For example, the pixel defining film 180 may define the pixels P by separating the first electrodes 171 from each other. The pixel defining film 180 may be disposed to cover the edge of the first electrode 171 such that a portion of the first electrode 171 is exposed by the pixel defining film 180. The pixel defining film 180 may be formed of an organic film such as acryl resin, epoxy resin, phenolic resin, polyamide resin, polyimide resin and the like.

Each of the pixels P refers to a region where the first electrode 171, the organic light-emitting layer 172 and the second electrode 173 are sequentially stacked and holes from the first electrode 171 and electrons from the second electrode 173 are combined with each other in the organic light-emitting layer 172 to emit light.

The organic light-emitting layer 172 may be disposed on the first electrode 171 and the pixel defining film 180. The organic light-emitting layer 172 may include an organic material to emit light in a predetermined color. For example, the organic light-emitting layer 172 may include a hole transporting layer, an organic material layer, and an electron transporting layer. In this case, the organic light-emitting layer 172 of a red pixel may emit red light, the organic light-emitting layer 172 of a green pixel may emit green light, and the organic light-emitting layer 172 of a blue pixel may emit blue light. In addition, the organic light-emitting layers 172 of the pixels P may emit white light, in which case the red pixel may further include a red color filter layer, the green pixel may further include a green color filter layer, and the blue pixel may further include a blue color filter layer.

The second electrode 173 is disposed on the organic light-emitting layer 172. The second electrode 173 may be disposed to cover the organic light-emitting layer 172. The second electrode 173 may be a common layer shared by the pixels P. A capping layer may be disposed on the second electrode 173.

In the top emission structure, the second electrode 173 may be formed of transparent conductive oxide (TCO) such as ITO or IZO capable of transmitting light or a semi-transmissive conductive material such as magnesium (Mg), silver (Ag), or an alloy of magnesium (Mg) and silver (Ag). When the second electrode 173 is formed of a semi-transmissive metal material, the light emission efficiency can be increased due to a micro-cavity effect.

In the bottom emission structure, the second electrode 173 may be formed of a metal material, having high reflectivity, such as a stacked structure (Ti/Al/Ti) of aluminum (Al) and titanium (Ti), a stacked structure (ITO/AI/ITO) of Al and ITO, an APC alloy, a stacked structure (ITO/APC/ITO) of an APC alloy and ITO, or the like. The APC alloy is an alloy of silver (Ag), palladium (Pd) and copper (Cu).

The second substrate SUB2 is disposed on the light-emitting element layer EML, and the touch sensor layer TSL is disposed on the second substrate SUB2. The touch sensor layer TSL includes the first touch electrodes TE, the second touch electrodes RE, the connection electrodes CE, electrostatic induction electrodes ESD, the first touch signal lines TL1 to TLp, and the second touch signal lines RL1 to RLq. For simplicity of description, FIGS. 6 and 7 illustrate only the second touch electrodes RE, touch island electrodes TEI, which are disposed between the neighboring first touch electrodes TE, the connection electrodes CE, and the electrostatic induction electrodes ESD of the touch sensor layer TSL.

The connection electrodes CE and the electrostatic induction electrodes ESD are disposed on the second substrate SUB2. For example, the connection electrodes CE and the electrostatic induction electrodes ESD are directly disposed on the second substrate SUB2. For example, the connection electrodes CE and the electrostatic induction electrode ESD are disposed in the display area DA (or the touch sensor area TSA) of the second substrate SUB2.

Each of the connection electrodes CE connects the first touch electrode TE to the touch island electrode TEI. One end of each of the connection electrodes CE may be connected to the first touch electrode TE, and the other end thereof may be connected to the touch island electrode TEI.

The connection electrodes CE may be formed of an opaque metal conductive layer. For example, the connection electrodes CE may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. For this reason, to prevent the opening ratio of the pixel P from being lowered, the connection electrodes CE do not overlap the pixels P as shown in FIG. 7 and may be disposed to overlap the pixel defining film 180.

In addition, the connection electrodes CE should be designed narrowly in consideration of visibility aspects. In this case, a defect in the connection electrode CE may occur due to static electricity concentrated in an intersection area between the connection electrodes CE and the second touch electrode RE. The above-described electrostatic induction electrodes ESD may prevent a defect in the connection electrode CE by inducing static electricity toward themselves so that the aforementioned static electricity is not concentrated in the aforementioned intersection area.

The electrostatic induction electrodes ESD may be formed through the same process as the connection electrodes CE, and may include the same material as the connection electrodes CE. The electrostatic induction electrodes ESD may include the same metal material as the connection electrodes CE. The electrostatic induction electrodes ESD may include a different material from the first touch electrodes TE and the second touch electrodes RE. When the electrostatic induction electrodes ESD include a transparent conductive material, the visibility issue of the electrostatic induction electrodes ESD may be reduced or prevented even though the electrostatic induction characteristics of the electrostatic induction electrodes ESD may be reduced.

In an embodiment, the electrostatic induction electrodes ESD might not overlap the pixels P to prevent the opening ratio of the pixel P from being lowered, and may be disposed to overlap the pixel defining film 180.

One end of each of the electrostatic induction electrodes ESD is connected to the first touch electrode TE. The other end of each of the electrostatic induction electrodes ESD overlaps the second touch electrode RE. According to an embodiment of the present invention, the other end of each of the electrostatic induction electrodes ESD overlaps an extension portion EP of the second touch electrode RE. The second touch electrode RE includes the extension portion EP extending toward another second touch electrode RE, so the neighboring second touch electrodes RE may be integrated as a whole as their extension portions EP connect the second touch electrodes RE to each other.

A first insulating film 510 is disposed on the connection electrodes CE and the electrostatic induction electrodes ESD. The first insulating film 510 may be formed of an inorganic film, for example, a silicon nitride layer, a silicon oxy nitride layer, a silicon oxide layer, a titanium oxide layer, or an aluminum oxide layer.

The first touch electrodes TE, the touch island electrodes TEI, and the second touch electrodes RE are disposed on the first insulating film 510. For example, the first touch electrodes TE, the touch island electrodes TEI, and the second touch electrodes RE are disposed on the first insulating film 510 so as to correspond to the display area DA (or the touch sensor area TSA) of the substrate SUB2. The first touch electrode TE may be connected to the connection electrode CE through a first contact hole CT1 that penetrates the first insulating film 510 and exposes the connection electrode CE. The touch island electrode TEI may be connected to the connection electrode CE through a second contact hole CT2 that penetrates the first insulating film 510 and exposes the connection electrode CE. Accordingly, the first touch electrode TE and the touch island electrode TEI may be connected to each other through the connection electrode CE. Therefore, the first touch electrodes TE disposed in the second direction (Y-axis direction) in each of the plurality of columns may be electrically connected to each other.

Additionally, the first touch electrode TE may be connected to the electrostatic induction electrode ESD through a third contact hole CT3 that penetrates the first insulating film 510 and exposes the electrostatic induction electrode ESD.

The first touch electrodes TE, the touch island electrodes TEI, and the second touch electrodes RE may be formed of transparent metal oxide (TCO), such as ITO or IZO, capable of transmitting light. Accordingly, even when the first touch electrodes TE, the touch island electrodes TEI, and the second touch electrodes RE overlap the pixels P, the opening ratio of the pixel P does not decrease.

A second insulating film 520 is disposed on the first touch electrodes TE, the touch island electrodes TEI, and the second touch electrodes RE. The second insulating film 520 may be formed of an inorganic film, for example, a silicon nitride layer, a silicon oxynitride layer, a silicon oxide layer, a titanium oxide layer, or an aluminum oxide layer.

According to an embodiment, at least a part of each of the electrostatic induction electrodes ESD may overlap the second touch electrode RE in a connection area CNA. For example, the other end of each of the electrostatic induction electrodes ESD may overlap the second touch electrode RE in the aforementioned connection area CNA. For example, the electrostatic induction electrodes ESD, which are connected to a first touch electrode TE, may be disposed between a pair of connection electrodes CE in the first direction (X-axis direction). FIG. 6 shows an example where eight electrostatic induction electrodes ESD overlap the second touch electrode RE in the connection area CNA. For example, the number of the electrostatic induction electrodes ESD overlapping the connection area CNA may be greater than the number of the connection electrodes CE defining that connection area CNA. However, the number of the electrostatic induction electrodes ESD overlapping the connection area CNA is not limited thereto, and may be modified in various ways. For example, the number of the electrostatic induction electrodes ESD overlapping the connection area CNA may be less than the number of the connection electrodes CE defining that connection area CNA.

According to an embodiment, the connection area CNA may be defined by the first touch electrodes TE, touch island electrodes TEI, and connection electrodes CE adjacent to each other, as shown in FIG. 6. For example, in plan view as shown in FIG. 6, the connection area CNA may be defined as an area surrounded by the two neighboring first touch electrodes TE, the two neighboring touch island electrodes TEI, and the four connection electrodes CE disposed adjacent to each other to connect the two first touch electrodes TE and the two touch island electrodes TEI to each other. For example, in plan view, the connection area CNA may be an area surrounded by the first touch electrodes TE, touch island electrodes TEI, and connection electrodes CE that are adjacent to each other and connected to each other.

According to an embodiment, the neighboring second touch electrodes RE may be connected to each other in the aforementioned connection area CNA. In other words, the neighboring second touch electrodes RE may be integrated as a whole in the connection area CNA. The aforementioned extension portion EP of the second touch electrode RE may be disposed in the connection area CNA so as to overlap the connection area CNA.

In this way, since at least a part of each of the electrostatic induction electrodes ESD overlaps the second touch electrode RE (for example, the extension portion EP of the second touch electrode RE) in the connection area CNA, static electricity can be more easily induced to the electrostatic induction electrodes ESD. For example, as static electricity is mainly concentrated in the center of the connection area CNA, by disposing at least a part of each of the electrostatic induction electrodes ESD closer to the center of the connection area CNA than the connection electrodes CE, the electrostatic induction electrodes ESD can more effectively block the inflow of static electricity to the connection electrodes CE that are disposed at the edge of the connection area CNA.

According to an embodiment, a length L of the electrostatic induction electrode ESD may be about 50 μm. The length L of the electrostatic induction electrode ESD may be defined as, for example, a distance between one end (for example, a portion connected to the first touch electrode TE) of the electrostatic induction electrode ESD and the other end (for example, a portion overlapping the second touch electrode RE) of the electrostatic induction electrode ESD. However, the length L of the electrostatic induction electrode ESD is not limited thereto, and may be modified in various ways.

According to an embodiment, a width W of the connection electrode CE may be about 6.7 μm. The width W of the connection electrode CE may be a size in a direction perpendicular to the longitudinal direction of the connection electrode CE. For example, as the length of the connection electrode CE may be defined as a distance between one end (for example, a portion connected to the first touch electrode TE) of the connection electrode CE and the other end (for example, a portion connected to the touch island electrode TEI) of the connection electrode CE, the width W of the connection electrode CE may be the size of the connection electrode CE in the direction that is perpendicular to the length of the connection electrode CE described above. However, the width W of the connection electrode CE is not limited thereto, and may be modified in various ways.

According to an embodiment, when the width W of the connection electrode CE is about 6.7 μm, the length L of the electrostatic induction electrode ESD may be about 50 μm.

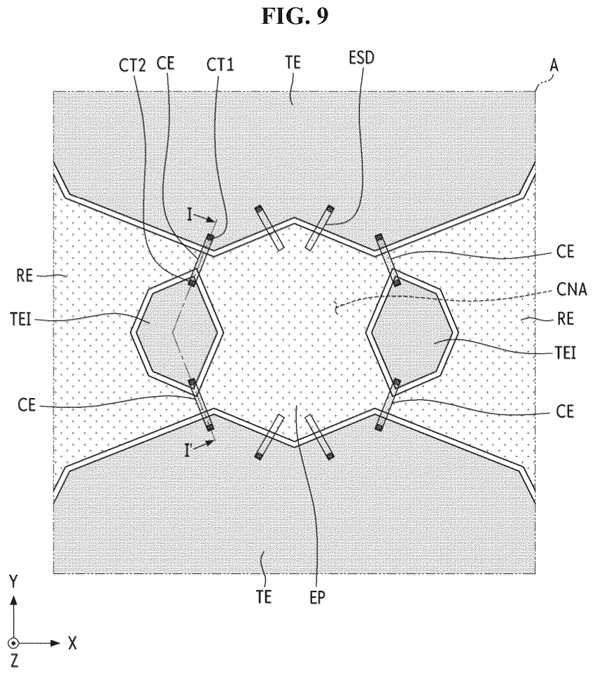

FIG. 9 is an enlarged plan view showing an example of area A of FIG. 5.

The display device 10 of FIG. 9 differs from the display device 10 of FIG. 6 described above in the number of the electrostatic induction electrodes ESD, and the following description will mainly focus on this difference.

As shown in FIG. 9, the number of the electrostatic induction electrodes ESD overlapping the second touch electrode RE in the connection area CNA may be four. For example, the number of the electrostatic induction electrodes ESD overlapping the connection area CNA may be equal to the number of the connection electrodes CE that define the connection area CNA.

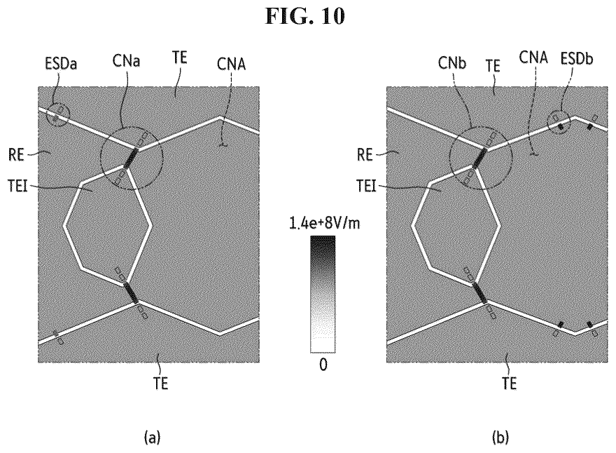

FIG. 10 is a diagram for explaining effects of the electrostatic induction electrode ESD according to an embodiment.

In FIG. 10, (a) shows, in grayscale levels, the magnitude of static electricity (for example, the intensity of an electric field) induced in an electrostatic induction electrode ESDa of a display device of a comparative example when the static electricity flows into the display device of the comparative example, and (b) shows, in grayscale levels, the magnitude (e.g., the intensity of an electric filed) of static electricity induced in an electrostatic induction electrode ESDb of the display device 10 according to an embodiment when the static electricity flows into the display device 10 of an embodiment. For example, the electrostatic induction electrode ESDb of (b) of FIG. 10 may be the same as the electrostatic induction electrode ESD of FIGS. 6 to 9 that are described above.

In FIG. 10, the darker the grayscale level of the electric field, the higher the intensity of the electric field.

As shown in (a) of FIG. 10, when the electrostatic induction electrode ESDa overlaps the second touch electrode RE outside the connection area CNA, the intensity of the electric field that is induced in the electrostatic induction electrode ESDa is found to be relatively low.

In addition, as shown in (b) of FIG. 10, when the electrostatic induction electrode ESDb overlaps the second touch electrode RE inside the connection area CNA, the intensity of the electric filed that is induced in the electrostatic induction electrode ESD is found to be relatively high. In other words, the intensity of the electric field induced in the electrostatic induction electrode ESDb of the display device 10 according to an embodiment is found to be higher than the intensity of the electric field induced in the electrostatic induction electrode ESDa of the display device of the comparative example.

Therefore, when the electrostatic induction electrode ESDb is disposed in the connection area CNA, as in the display device 10 of an embodiment, a greater amount of static electricity is induced into the electrostatic induction electrode ESDb, so that damage to the connection electrode CE can be prevented.

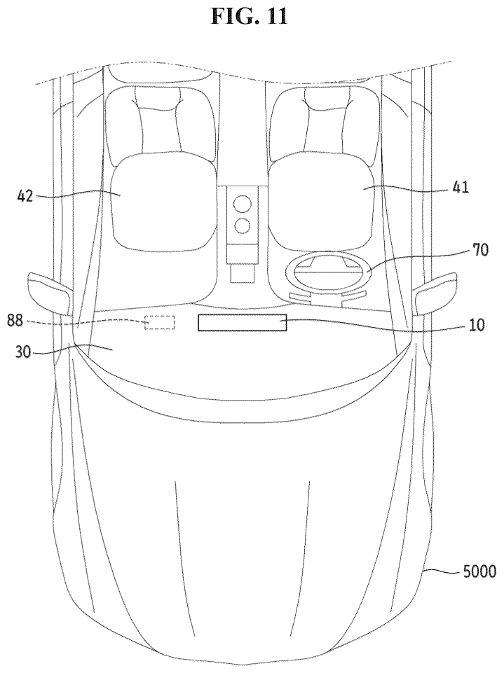

FIG. 11 is a schematic diagram illustrating a vehicle 5000 including the display device 10 according to one embodiment.

The display device 10 according to one embodiment may be, for example, the display device 10 applied to the vehicle 5000.

The vehicle 5000 may include a body that forms the exterior of the vehicle 5000, and an interior space that is defined by the body. Additionally, the vehicle 5000 may further include a dashboard 30, a driver's seat 41, a passenger seat 42, and a steering wheel 70 disposed in the interior space of the vehicle 5000. Also, the vehicle 5000 may further include a vehicle controller 88 that collects vehicle information from the vehicle 5000 and controls the vehicle 5000 based on the collected vehicle information.

The display device 10 according to an embodiment may be provided in the interior space of the vehicle 5000. For example, the display device 10 may be disposed on the dashboard 30. For example, the display device 10 may be disposed on the dashboard 30 that is between the driver's seat 41 and the passenger seat 42. However, without being limited thereto, the display device 10 may be disposed at various locations in the vehicle 5000. For example, the display device 10 according to an embodiment may be disposed on backsides of the driver's seat 41 and the passenger seat 42 as well.

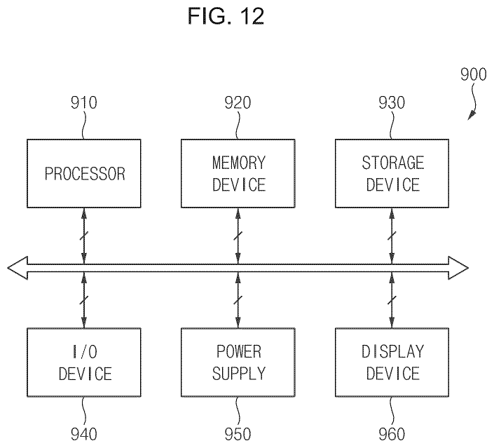

FIG. 12 is a block diagram illustrating an electronic device according to an embodiment.

Referring to FIG. 12, in an embodiment, an electronic device 900 may include a processor 910, a memory device 920, a storage device 930, an input/output (“I/O”) device 940, a power supply 950, and a display device 960. Here, the display device 960 may correspond to the display device 10 as shown in for example FIGS. 1, 2 and 3. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments of the present invention are not limited thereto, and in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

While the present invention has been particularly shown and described with reference to embodiments thereof, it will be apparent to those of ordinary skill in the art that various changes in form and detail may be made thereto without departing from spirit and scope of the present invention.

What is claimed is:

1. A touch sensing unit comprising:
a substrate;
a plurality of first touch electrodes disposed in a touch sensor area of the substrate;
a plurality of touch island electrodes disposed between neighboring first touch electrodes;
a plurality of connection electrodes connecting the neighboring first touch electrodes to the plurality of touch island electrodes;
a plurality of second touch electrodes connected to each other in a connection area that is defined by the neighboring first touch electrodes, the plurality of touch island electrodes and the plurality of connection electrodes, wherein plurality of second touch electrodes are disposed in a touch sensor area of the substrate; and
an electrostatic induction electrode connected to the first touch electrode and overlapping the second touch electrode,
wherein at least a part of the electrostatic induction electrode overlaps the second touch electrode in the connection area.

2. The touch sensing unit of claim 1, wherein a first end of the electrostatic induction electrode is connected to the first touch electrode through a contact hole that penetrates an insulating film, and
a second end of the electrostatic induction electrode overlaps the second touch electrode with the insulating film interposed therebetween.

3. The touch sensing unit of claim 1, wherein an extension portion of each of neighboring second touch electrodes of the plurality of second touch electrodes is disposed in the connection area.

4. The touch sensing unit of claim 3, wherein at least a part of the electrostatic induction electrode overlaps the extension portion of a second touch electrode of the neighboring second touch electrodes in the connection area.

5. The touch sensing unit of claim 1, wherein the electrostatic induction electrode is of a plurality of electrostatic induction electrodes, and
at least a part of each of the plurality of electrostatic induction electrodes overlaps the second touch electrode in the connection area.

6. The touch sensing unit of claim 5, wherein a number of the plurality of electrostatic induction electrodes and a number of the plurality of connection electrodes are different from each other.

7. The touch sensing unit of claim 1, wherein a length of the electrostatic induction electrode is about 50 μm.

8. The touch sensing unit of claim 1, wherein a width of at least one of the plurality of connection electrodes is about 6.7 μm.

9. The touch sensing unit of claim 1, wherein a width of at least one of the plurality of connection electrodes is about 6.7 μm, and
A length of the electrostatic induction electrode is about 50 μm.

10. A display device comprising:
a display panel; and
a touch sensing unit disposed on the display panel,
wherein the touch sensing unit comprises:
a substrate;
a plurality of first touch electrodes disposed in a touch sensor area of the substrate;
a plurality of touch island electrodes disposed between neighboring first touch electrodes;
a plurality of connection electrodes connecting the neighboring first touch electrodes to the plurality of touch island electrodes;
a plurality of second touch electrodes connected to each other in a connection area that is defined by the neighboring first touch electrodes, the plurality of touch island electrodes and the plurality of connection electrodes, wherein the plurality of second touch electrodes are disposed in a touch sensor area of the substrate; and
an electrostatic induction electrode overlapping the first touch electrode and the second touch electrode,
wherein at least a part of the electrostatic induction electrode overlaps the second touch electrode in the connection area.

11. The display device of claim 10, wherein a first end of the electrostatic induction electrode is connected to the first touch electrode through a contact hole penetrating an insulating film, and
a second end of the electrostatic induction electrode overlaps the second touch electrode with the insulating film interposed therebetween.

12. The display device of claim 10, wherein an extension portion of each of neighboring second touch electrodes of the plurality of second touch electrodes is disposed in the connection area.

13. The display device of claim 12, wherein at least a part of the electrostatic induction electrode overlaps the extension portion of a second touch electrode of the neighboring second touch electrodes in the connection area.

14. The display device of claim 10, wherein the electrostatic induction electrode is of a plurality of electrostatic induction electrode, and
at least a part of each of the plurality of electrostatic induction electrodes overlaps the second touch electrode in the connection area.

15. The display device of claim 14, wherein a number of the plurality of electrostatic induction electrodes and a number of the plurality of connection electrodes are different from each other.

16. The display device of claim 10, wherein a width of at least one of the plurality of connection electrodes is about 6.7 μm, and
a length of the electrostatic induction electrode is about 50 μm.

17. A vehicle comprising:
a body;
an interior space defined by the body; and
a display device disposed in the interior space,
wherein the display device comprises:
a substrate;
a plurality of first touch electrodes disposed in a touch sensor area of the substrate;
a plurality of touch island electrodes disposed between neighboring first touch electrodes;
a plurality of connection electrodes connecting the neighboring first touch electrodes to the plurality of touch island electrodes;
a plurality of second touch electrodes connected to each other in a connection area that is defined by the neighboring first touch electrodes, the plurality of touch island electrodes and the plurality of connection electrodes, wherein the plurality of second touch electrodes are disposed in a touch sensor area of the substrate; and
an electrostatic induction electrode connected to the first touch electrode and overlapping the second touch electrode,
wherein at least a part of the electrostatic induction electrode overlaps the second touch electrode in the connection area.

18. The vehicle of claim 17, wherein a first end of the electrostatic induction electrode is connected to the first touch electrode through a contact hole penetrating an insulating film, and
a second end of the electrostatic induction electrode overlaps the second touch electrode with the insulating film interposed therebetween.

19. The vehicle of claim 17, wherein an extension portion of each of neighboring second touch electrodes of the plurality of second touch electrodes is disposed in the connection area.

20. The vehicle of claim 19, wherein at least a part of the electrostatic induction electrode overlaps the extension portion of a second touch electrode of the neighboring second touch electrodes in the connection area.

21. An electronic device, comprising:
a display device; and
a power supply configured to provide power to the display device,
wherein the display device comprises:
a display panel; and
a touch sensing unit disposed on the display panel,
wherein the touch sensing unit comprises:
a substrate;
a plurality of first touch electrodes disposed in a touch sensor area of the substrate;
a plurality of touch island electrodes disposed between neighboring first touch electrodes;
a plurality of connection electrodes connecting the neighboring first touch electrodes to the plurality of touch island electrodes;
a plurality of second touch electrodes connected to each other in a connection area that is defined by the neighboring first touch electrodes, the plurality of touch island electrodes and the plurality of connection electrodes, wherein the plurality of second touch electrodes are disposed in a touch sensor area of the substrate; and
an electrostatic induction electrode connected to the first touch electrode and overlapping the second touch electrode,
wherein at least a part of the electrostatic induction electrode overlaps the second touch electrode in the connection area.

22. The electronic device of claim 21, wherein a first end of the electrostatic induction electrode is connected to the first touch electrode through a contact hole that penetrates an insulating film that is disposed on the electrostatic induction electrode, and
a second end of the electrostatic induction electrode overlaps the second touch electrode with the insulating film interposed therebetween.

23. The electronic device of claim 21, wherein neighboring second touch electrodes of the plurality of second touch electrodes are connected to each other through an extension portion that is disposed in the connection area.

24. The electronic device of claim 23, wherein at least a portion of the electrostatic induction electrode overlaps the extension portion in the connection area.

25. The electronic device of claim 24, wherein the electrostatic induction electrode does not contact the extension portion.

26. The electronic device of claim 21, wherein the electrostatic induction electrode is disposed between a pair of neighboring connection electrodes of the plurality of connection electrodes in a plan view.
